(19) United States
(12) Patent Application Publication
(10) Pub. No.: US 2008/0044986 A1
(43) Pub. Date: Feb. 21, 2008

(54) METHOD FOR IMPROVED DIELECTRIC PERFORMANCE

(76) Inventors: Olaf Storbeck, Dresden (DE); Wieland Pethe, Dresden (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/465,575

(22) Filed: Aug. 18, 2006

(51) Int. Cl. H01L 21/477

(52) U.S. Cl. 438/471; 438/795; 438/778

(57) ABSTRACT

A method of decreasing the density of dielectric interface traps in an integrated circuit device. In accordance with the teachings of the present invention, the method includes providing a semiconductor substrate, processing the semiconductor substrate to form an integrated circuit device, such as a field effect transistor including forming a dielectric layer, and heating the dielectric layer in an atmosphere comprising at least one gaseous halogen compound.

### BACKGROUND OF THE INVENTION

1. Field of the Invention

The present invention relates to a method of decreasing the density of dielectric interface traps in integrated circuit devices including memory on an integrated circuit in a semiconductor substrate.

2. Description of the Related Art

In a conventional transistor, a gate is separated from the source and drain by a dielectric layer. When a sufficient voltage level is applied to the gate the transistor turns on and current flows between the source and the drain of the transistor. Integrated circuits are formed with multiple transistors on a semiconductor substrate.

Modern integrated electronic circuits contain a myriad of densely packed electronic elements—such as resistors, capacitors or transistors—on a single semiconductor substrate chip. While often millions of such elements form an integrated circuit, nowadays the size of a single chip is far below a squared inch. Over recent years, the semiconductor industry has established very sophisticated and reliable manufacturing processes for routinely fabricating highly integrated circuits.

Electronic data memories, such as dynamic random access memory or DRAM, are generally formed as a memory cell matrix on a semiconductor wafer via silicon planar technology processes. Other processes conventionally used to form DRAM and integrated circuit devices in general, are the so-called MOSFET and CMOS processes. Integration is very critical and closely related to the overall device performance in electronic data memories. Such electronic data memory devices generally store their information content in capacitors, which capacitors, in turn, are operated via so-called selection transistors. One memory cell may then comprise at least one capacitor and one transistor. During a reading or writing operation, the capacitor is charged or discharged with an electrical charge corresponding to the respective data unit, via the selection transistor.

Increasing the performance of an electronic data memory translates to integrating as many capacitors and transistors as possible in a substrate chip of a given—and limited—size. Similar requirements also apply to related types of electronic integrated devices, for example, to microprocessors or to other highly integrated electronic circuitries.

A significant main focus in the technological development of semiconductor memories, in particular DRAMs, is the selection transistor and storage capacitor. The selection transistor of the memory cell is usually formed as a planar field effect transistor alongside the storage capacitor on the semiconductor surface, one source/drain electrode being connected to the inner electrode of the storage capacitor. The selection transistor of a memory cell may also be formed as a vertical field effect transistor alongside the storage capacitor. In order to provide for a sufficient storage capacitance in conjunction with a small cross-sectional area, the storage capacitors may be produced three-dimensionally in the form of trench capacitors. In the case of such trench capacitors, a trench is etched into the semiconductor substrate and then filled with a dielectric intermediate layer and a first storage electrode. A doped region of the semiconductor substrate around the trench serves as a second storage electrode.

On account of the still increasing miniaturization of the memory cells, additional possibilities are being sought for simultaneously reducing the area requirement and increasing the memory cell performance. In the case of selection transistors, one possibility for decreasing the memory cell size is to replace conventional dielectric layers that typically exhibit low dielectric constant characteristics with higher dielectric constant materials. In the case of trench capacitors, one possibility for increasing the capacitance is to use very thin insulator layers having a high dielectric constant as a dielectric intermediate layer between the capacitor electrodes. Material combinations comprising thin silicon dioxide and silicon nitride layers are conventionally used as dielectric layers in memory cell structures, in both selection transistors and trench capacitors.

It becomes more and more difficult to maintain sufficient dielectric layer thicknesses in order to minimize leakage between the gate and semiconductor substrate, especially in the context of the cell area that constantly decreases from technology generation to technology generation. Up to now, the unprecedented growth of the semiconductor industry has been driven by scaling the geometric dimensions of integrated circuit components, including field effect transitors or FET components. Both gate dielectric thickness and gate length have been continuously reduced to enhance the electrostatic control of the channel potential and to increase transistor drive currents.

Dielectric layer scaling, however, is accompanied by an exponential increase of gate direct tunneling currents, while the advent of short channel effects for sub-micron gate-lengths has lead to increasing source-drain leakage currents. Both effects add up to a non-negligible percentage of overall chip power dissipation. Therefore, for sub-100 nm structures, consideration is being given to a material modification in the case of the dielectric layer. The aim is to replace the materials that are conventionally used for the gate dielectric layer in selection transistors and the dielectric intermediate layer in trench capacitors with materials that are distinguished by a higher dielectric constant, thus enabling the gate dielectric leakage to be decreased and the area-specific storage capacitance to be increased. Such materials are generally known as high-k dielectrics, examples of which are hafnium oxide, zirconium oxide, or oxides of the lanthanide series.

However, a common problem with incorporating high-k dielectrics into integrated circuit devices is the presence of what are called interface traps. Interface traps are electrically active defects located at the interface between different materials, such as dielectric and semiconductor materials, that are capable of trapping and de-trapping charge carriers. For example, ultraviolet light may induce an increased density of electronic states or traps at semiconductor-insulator interfaces, or—in general—at all interfaces of two facing materials that possess different electronic properties. This locally enhanced density of states may cause generation/recombination currents via a combination of tunneling and field emission. Since integrated electronic entities become more and more sensitive upon miniaturization as far as signal accuracy is concerned, such effects are very undesirable. Above all, an uncontrolled increase of the density of interface traps may interfere with capacitors and transistors causing the destruction of memory content or severely limiting the reliable operation of the electronic entities of a memory device. In particular, the so-called data retention time of an electronic memory device may be drastically reduced, the retention time being defined as the time span a memory cell may reliably store a respective logical state.

While high k dielectric materials allow thicker, less leaky film layers due to their increased dielectric constant in selection transistors, their interface properties, especially the density of interface traps (DIT), are significantly worse compared with SiO₂, although interface traps are not completely nonexistent in SiO₂ or other conventional dielectric materials. To compensate for process, activity and environmental variations in a transistor device, a ratio of a transistor on-current to a transistor off-current within the transistor device is detected, which is commonly referred to as the ION/IOFF ratio. Excessive DIT will lead to reduced carrier mobilities and low ION/IOFF ratios. Other problems linked to DIT are increased threshold voltage shifts and poor hot carrier stress immunity, both leading to lower device lifetime. For DRAM products and selection transistors in particular, high DIT is related to low retention time. In sum, interface traps have an adverse effect on integrated circuit performance.

DIT may be reduced by passivating open bonds at dielectric interfaces, such as silicon-dielectric interfaces, with various chemicals, some examples of which are compounds comprising halogen elements. However, halogens are only introduced as by-products of other process steps. For example, silicon deposition using the compound Si₂Cl₄ introduces chlorine; tungsten silicide film deposition, the so-called WSi deposition using the compound WF₆, introduces fluorine. Although hydrogen also passivates open bonds and reduces DIT through a relatively easy annealing step, the poor binding of hydrogen at the silicon-dielectric interface may lead to bad reliability behavior. Moreover, the incorporation of halogens during a gate stack deposition step will not be used anymore because of low conductivity of the created gate material. Fluorine implants may also reduce DIT but suffers from the potential draw back of a relatively high cost associated with that solution as well as the wrong placement of the fluorine in the silicon, instead of at the interface where interface traps occur. Additionally, fluorine implants require post implantation anneals in order to let the fluorine diffuse to the silicon-dielectric interface thereby increasing valuable process time.

### SUMMARY OF THE INVENTION

According to one embodiment of the present invention, there is a method of decreasing the density of dielectric traps in an integrated circuit device. The method includes providing a semiconductor substrate for forming an integrated circuit device including forming at least one dielectric layer on the semiconductor substrate. The semiconductor substrate, including the dielectric layer, is then heated in an atmosphere comprising at least one gaseous halogen compound.

According to another embodiment of the present invention, there is a method of decreasing the density of dielectric interface traps in an integrated memory device. The method includes providing a semiconductor substrate for forming an integrated circuit device. Forming the integrated circuit device includes forming a field effect transistor with at least one dielectric layer on the semiconductor substrate. Next, the semiconductor substrate, including the dielectric layer, is heated in a pressurized atmosphere comprising at least one gaseous halogen compound.

### BRIEF DESCRIPTION OF THE DRAWINGS

The above recited features of the present invention will become clear form the following description, taken in conjunction with the accompanying drawings. It is to be noted, however, that the accompanying drawings illustrate only typical embodiments of the present invention and are, therefore, not to be considered limiting of the scope of the invention. The present invention may admit other equally effective embodiments. The present invention will be described below in more details with reference to the embodiments and drawings.

FIG. 1 shows a circuit diagram of a dynamic memory cell in a DRAM memory.

FIG. 2 shows a DRAM memory cell including a planar selection transistor.

FIG. 3 shows a DRAM memory cell including a vertical selection transistor.

FIG. 4 shows a conventional MOS type transistor device.

FIG. 5 shows an integrated circuit device which may be formed according to an embodiment of the present invention.

FIG. 6 shows an integrated circuit device which may be formed according to an embodiment of the present invention.

FIG. 7 is a diagrammatic, cross-sectional view of a RTP unit commonly used in processing integrated circuit devices.

### DETAILED DESCRIPTION OF THE PREFERRED EMBODIMENT

Various aspects of the present invention can provide particular advantages for an improved integrated circuit device comprising at least one dielectric layer and a method of decreasing the density of dielectric interface traps in an integrated circuit device. In general, the integrated circuit device may be fabricating with silicon planar technology manufacturing processes, as well as MOSFET and CMOS processes. Other well known processes for integrated circuit device manufacture are also contemplated for application of the invention.

The invention will be explained not only with reference to the production of integrated circuits such as a DRAM memory cell, particularly the selection transistor of a DRAM cell, but also storage capacitors such are formed during production of DRAM storage cells on a silicon base. However, these types of circuits are only described and used in an exemplary fashion; other highly integrated circuits have dielectric layers throughout their structure and thus could also utilize the invention to reduce the density of interface traps in the dielectric layers. Not only may other types of integrated circuits' manufacturing processes utilize the invention but also other semiconductor substrates other than silicon, such as germanium.

Furthermore, the invention may be utilized in processing planar selection transistors, vertical selection transistors, and storage cells in the form of trench capacitors, all used for DRAM memory devices. The invention may also be used in the production of other types of storage cells in DRAM memory processing, for example stacked capacitors.

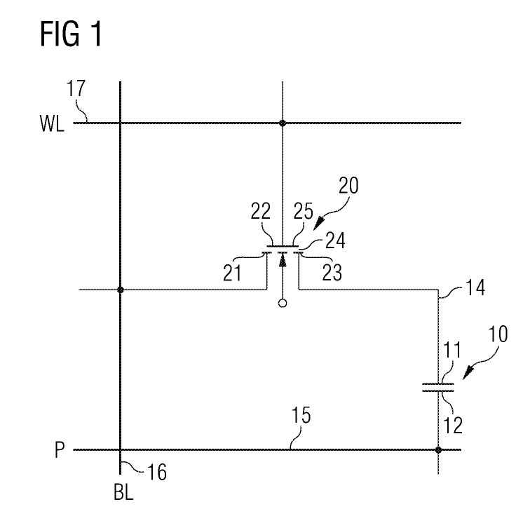

Turning now to FIG. 1, a circuit diagram of a one-transistor memory cell such as is predominantly used in DRAM memories, is illustrated. The one-transistor memory cell comprises a storage capacitor 10 and a selection transistor 20. In this case, the selection transistor 20 is formed as a field effect transistor and has a first source/drain electrode 21 and a second source/drain electrode 23, between which an active region 22 is arranged. Above the active region 22 are the gate insulator layer or dielectric layer 24 and gate electrode 25 together which act like a plate capacitor and can influence the charge density in the active region 22 in order to form or block a current-conducting channel between the first source/drain electrode 21 and the second source/drain electrode 23.

The second source/drain electrode 23 of the selection transistor 20 is connected to a first electrode 11 of the storage capacitor 10 via a connecting line 14. A second electrode 12 of the storage capacitor 10 is in turn connected to a capacitor plate 15, which is preferably common to all the storage capacitors of the DRAM memory cell arrangement. The first electrode 21 of the selection transistor 20 is furthermore connected to a bit line 16 in order that the information stored in the storage capacitor 10 in the form of charges can be written-in and read-out. In this case, the write-in or read-out operation is controlled via a word line 17, which is at the same time the gate electrode 25 of the selection transistor 20. The write-in or read-out operation occurs by applying a voltage to produce a current-conducting channel in the active region 22 between the first source/drain electrode 21 and the second source/drain electrode 23.

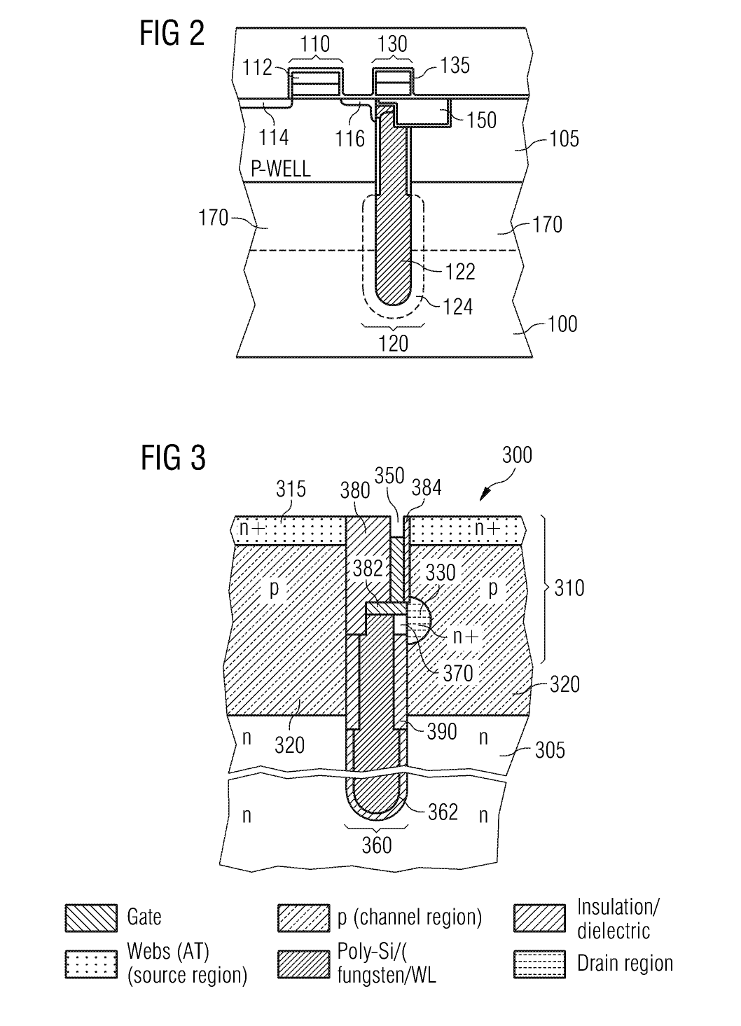

FIGS. 2 and 3 each show a DRAM memory cell having a planar selection transistor and a vertical selection transistor respectively. It should be noted that FIGS. 2 and 3 are used for exemplary purposes illustrating both planar and selection transistor types used in DRAM memory cells. Other types of DRAM cell configurations using planar and vertical selection transistors are known in the prior art; the present invention may be used on all of them to reduce the density of interface traps such as may occur during formation of planar and vertical selection transistors.

A conventional trench capacitor DRAM cell 100 with a planar transistor is shown in FIG. 2. Typically such cells are interconnected forming a cell array by wordlines and bitlines to form a DRAM chip. The DRAM cell includes a selection transistor 110. The selection transistor includes a gate 112, source 114, and drain 116 in a semiconductor substrate 105. Generally, the semiconductor substrate 105 is lightly doped with a dopant having a first conductivity. The drain 116 and source 114 are formed by implanting dopants having a second conductivity into the semiconductor substrate 105. The designation of the drain and source may change depending on the operation of the transistor. For convenience, the terms drain and source are interchangable.

The DRAM cell also includes a trench capacitor 120 formed in the semiconductor substrate 105. The trench capacitor 120 is typically filled with polysilicon 122 heavily doped with dopants having a second conductivity. The polysilicon serves as one plate of the capacitor. The other plate of the capacitor is formed by a buried plate 124, also having a second conductivity. Connection of the selection transistor 110 to the inner capacitor plate is achieved via a strap 135. The strap 135 is formed by providing dopants having the same conductivity as the source. As shown, a buried strap is employed to connect the junction of the memory transistor to the inner plate of the trench (node). Other techniques, such as a surface strap, for connecting the transistor to the capacitor are also useful.

A buried well 170, also having dopants of the second conductivity, is provided below the surface of the semiconductor substrate. Typically, the well is lightly doped. The buried well serves to connect the buried plates of the individual DRAM cells in the array together. Generally, the gate and source form a wordline and bitline, respectively, in the DRAM array. Activation of the transistor by providing the appropriate voltage at the wordline and bitline junction enables data to be written-in or read-out from the trench capacitor. A shallow trench isolation 150 is provided to isolate the DRAM cell from other cells or devices. To facilitate efficient use of substrate area, a wordline 130, which is not connected to the cell, is typically formed over the trench.

FIG. 3 shows a cross section through a conventional trench capacitor DRAM cell 300 with a vertical transistor 310. In a corresponding process, bulk, source and drain regions of the FET selection transistors are formed in the silicon-filled active webs. FIG. 3 shows transistor sections of the FET selection transistors, which, in the active web sections, have an n⁺-type source region 315, a channel-forming p-type region 320 and an n⁺-type drain region 330. Each of these regions are formed on, or in where applicable, a semiconductor substrate 305. FIG. 3 also shows a storage capacitor 360 which are formed in a deep trench and are in each case represented by a capacitor electrode 362 conventionally made of polysilicon and an insulating dielectric 390. The capacitor electrode 362 of the storage capacitors is in contact via a conductive section 370 with the drain electrode 330 of the associated selection transistor.

FIG. 3 also shows insulating/dielectric layers 380, 382, and 384 in each case for the insulation of the gate 350 from channel-forming p-type regions 320 and drain 330, on the one hand, and from conductive capacitor electrode section 362, on the other hand. The gate 350 simultaneously serves as a word line for the memory cell array assigned to the FIG. 3 transistor array. Furthermore, source region 315 represented as a covering layer in FIG. 1, serves for producing a source terminal of the vertical FET transistors with an assigned bit line (not shown).

The previous Figures are shown to orient the reader to the preferred application of the inventive process, that of decreasing dielectric traps in memory cells, in particular the selection transistor within DRAM memory cells of both the planar and vertical type. With increasing miniaturization of the memory cells and given a scaling size of less than 100 nm however, additional measures are necessary in order to be able to fulfill the three basic requirements of a dynamic memory cell in a DRAM memory. The three basic requirements are first, a sufficiently large storage capacitance of approximately 25 to 50 fF which is necessary for reliable detection of the charge stored in the storage capacitor; second, a packing-dense and structure-friendly cell layout which provides for a minimum chip area and thus provides for reduced costs; and lastly high selection transistor performance, in particular a high write-in and read-out current with low reverse current at the same time.

One way to fulfill both the second and third requirements of DRAM memory cell is to control the gate dielectric layer thickness and length. The gate dielectric layer, which serves as insulator between the gate and channel, should be made as thin as possible to increase the channel conductivity and performance when the transistor is on and to reduce subthreshold leakage when the transistor is off. However, with current gate dielectric layer thicknesses of around 1.2 nm (which in silicon is about 5 atoms thick) the quantum mechanical phenomenon of electron tunneling occurs between the gate and channel, leading to increased power consumption.

In DRAM memory cells, the dielectric gate layer of the selection transistor and the dielectric intermediate layer of the storage capacitor are conventionally made of silicon dioxide (SiO₂) and/or silicon nitride (Si₃N₄) layers. Silicon oxynitride (SiON) is another conventional dielectric material increasingly used as the integrated circuits themselves decrease in size. Alternatively, the dielectric layer may be made of the so called “high-k dielectric” materials that have a higher dielectric constant, and hence their name. High-k dielectrics typically have a dielectric constant, k, greater than 3.9. High-k dielectric materials that have a larger dielectric constant than silicon dioxide, such as group IVb metal silicates e.g. hafnium and zirconium silicates and oxides, are now being researched to reduce the gate leakage. Increasing the dielectric constant of the gate dielectric material allows a thicker layer while maintaining a high capacitance. The higher thickness reduces the tunneling current between the gate and the channel. Replacing conventional dielectric materials with high-k materials makes it possible to reduce the selection transistor and trench capacitor dimensioning of DRAM memory cells, and at the same time to maintain the high selection transistor performance and the storage capacitance required for reliable detection. High-k dielectrics are not only available in the case of selection transistors and trench capacitors used in DRAM cell production, but also any type of integrated circuit device where decreasing the size is important.

Various dielectric materials have been identified as high-k dielectric materials. Some preferred examples of dielectric materials in this case are binary oxides, such as e.g. tantalum oxide (Ta₂O₅) having a dielectric constant of 25. The use of aluminum oxide (Al₂O₃) having a dielectric constant of 10 is also advantageous. Moreover, hafnium oxide (HfO₂) having a dielectric constant of 50 to 60, and zirconium oxide (ZrO₂) having a dielectric constant of 11 to 25 are also suitable for use as a high-k dielectric material. Lanthanum oxide (La₂O₃) and yttrium oxide (Y₂O₃) having a dielectric constant of 20 to 25 and 11 to 12 respectively, may also be used. These binary oxides typically exhibit temperature stabilities between 800° C. and 830° C.

Furthermore, aluminum oxide tertiary compounds may also be used as a high-k dielectric. In particular compounds with hafnium, zirconium and lanthanum, for example aluminum hafniate (Hf—Al—O), aluminum zirconate (AlₓZr₁₋ₓO₂) or lanthanum-aluminum-oxide (La—Al—O), are suitable for this. Furthermore, high-k dielectrics may also be produced from silicate compounds, such as hafnium silicate (HfSiO₄), zirconium silicate (ZrSiO₄), lanthanum silicates (La—Si—O) or yttrium silicates (Y—Si—O). The aluminum and silicate tertiary compounds are distinguished by a dielectric constant of above 14 with temperature stability up to 900° C.

Moreover, further individual or mixed oxides or nitrides of the fourth or fifth secondary group and of the third and fourth main groups are suitable as high-k dielectrics. Other suitable compounds used for high-k dielectrics include gadolinium oxide (Gd₂O₃), ytterbium oxide (Yb₂O₃), dysprosium oxide (Dy₂O₃), niobium oxide (Nb₂O₅), strontium titanate (SrTiO₃), and barium strontium titanate (BaₓSr₁₋ₓTiO₃). Titanium oxide (TiO₂) and hafnium-silicon-oxy-nitride (HfSiON) are also preferable materials to produce high-k dielectric layers during an integrated circuit manufacturing process. It will be noted that sub variable x, used to denote ratios between chemical elements within any of the high-k compounds listed above, represent any fraction between 0 and 1.

However, use of high-k dielectrics to replace silicon dioxide (SiO₂) and/or silicon nitride layers (Si₃N₄) that are conventionally used sometimes creates other drawbacks. One common drawback is the presence of what are called interface traps. Interface traps are electrically active defects located at the interface between different materials, such as dielectric and semiconductor materials, that are capable of trapping and de-trapping charge carriers. Since integrated electronic entities become more and more sensitive upon miniaturization as far as signal accuracy is concerned, such effects are very undesirable. Above all, an uncontrolled increase of the density of interface traps may interfere with capacitors and transistors causing the destruction of memory content or severely limiting the reliable operation of the electronic entities of a memory device. In particular, the so-called data retention time of an electronic memory device may be drastically reduced, the retention time being defined as the time span a memory cell may reliably store a respective logical state.

While high k dielectric materials allow thicker, less leaky film layers due to their increased dielectric constant, their interface properties, especially the density of interface traps (DIT), are significantly worse compared with SiO₂, although interface traps are not completely nonexistent in SiO₂ or other conventional dielectric materials. Excessive DIT will lead to reduced carrier mobilities and low ION/IOFF ratios. Other problems linked to DIT are increased threshold voltage shifts and poor hot carrier stress immunity, both leading to lower device lifetime. For DRAM products and selection transistors in particular, high DIT is related to low retention time. In sum, interface traps have an adverse effect on integrated circuit performance.

In order to prevent the increased density of interface traps, the present invention includes a method of decreasing the density of the dielectric interface traps in an integrated circuit device, particularly DRAM memory. According to one embodiment of the present invention, the method includes steps as described in the following. In an initial step, a semiconductor substrate is provided for forming an integrated circuit device. The forming of the device is usually conducted by a combination of lithographic, etching, deposition, and other related techniques. Forming the integrated circuit device includes forming electronic elements, such as source/drain regions. In a next step, at least one dielectric layer is formed on the semiconductor substrate. The semiconductor substrate, including the electrical elements and dielectric layer, is then heated in an atmosphere comprising at least one gaseous halogen compound. Examples of this are shown in the subsequent Figures. Also, in some of the embodiments, the dielectric layer is formed on the other components of the DRAM memory cell, such as a doped source or drain region within the semiconductor substrate.

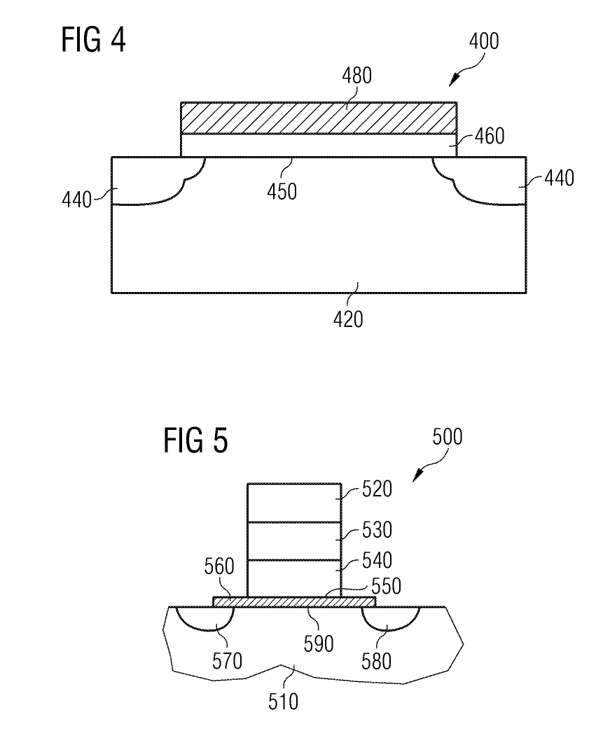

Referring now to FIG. 4, there is shown a cross-sectional representation of a conventional metal-oxide or MOS type transistor device 400. Active regions 440 are formed within a semiconductor substrate 420. The active region 440, commonly referred to as source or drain regions, can be any type of doped regions such as n+, p+, n−, or p− regions or collections of transistors formed within n-wells or p-wells. The active regions are separated from each other by the semiconductor substrate 420. Formation of a MOS type transistor is generally conducted by a combination of lithographic, etching, deposition, and other related techniques. A dielectric layer 460 is formed on the active or source/drain regions 34 and the semiconductor substrate 420. The dielectric layer 460 may be a silicon dioxide (SiO₂) and/or silicon nitride (Si₃N₄) layers which are conventionally used. Also, any high-k type dielectric may also be deposited above the semiconductor substrate 420 to form the dielectric layer. Preferably the high-k dielectric is HfSiON, but any of the examples discussed previously are acceptable alternatives. The dielectric layer 460 forms an interface 450 between the semiconductor substrate 420 and the source/drain regions 440.

During fabrication of a transistor device 400, dielectric interface traps may occur between the semiconductor substrate 420 and the dielectric layer 460 along the interface 450. To prevent this undesired contamination, the semiconductor substrate 420, including source/drain regions 440 and dielectric layer 460, is heated in an atmosphere comprising at least one gaseous halogen compound. Some preferable halogen compounds include fluorine (F₂), chlorine (Cl₂), hydrochloric acid (HCl), nitrogen trifluoride (NF₃) and halogenated hydrocarbons. Said halogenated hydrocarbons are preferably chlorinated hydrocarbons and fluorinated hydrocarbons. Said chlorinated hydrocarbons are preferably Trans-1,2-Dichloroethylene (TLC) (C₂H₂Cl₂), Trichloroethylene (TCE) (C₂HCl₃) and Trichloroethane (C₂H₃Cl₃). It is believed that heating the dielectric layer 460 in an atmosphere that includes at least one gaseous halogen compound passivates the interface 450 of the dielectric layer 460 and decreases the potential for interface traps to occur. A lead 480 located above the dielectric layer 460, often referred to as a gate, is formed on the dielectric layer 460.

In a preferred embodiment, the atmosphere is pressurized during the heating step between about 10 to 1000 Torr, with about 200 Torr being the most preferable pressure set point in a particular embodiment. Furthermore, the heating step is carried out at a temperature between about 500° C. to 1500° C., with the most preferable temperature set point between about 700° C. to 850° C. in a particular embodiment. Conventional rapid thermal processors (RTP) or other furnace type units may be used to heat the semiconductor substrate where a temperature set point can control the reaction chamber temperature of the RPT or furnace and thus maintain the desired temperature range. The atmosphere preferably comprises not only a gaseous halogen compound but includes inert gases such as argon (Ar), or other gases such as nitrogen (N₂) and oxygen (O₂). In a preferred embodiment, the atmosphere comprises a concentration between about 0.5 to 10 parts per million gaseous halogen compound. Additionally, the heating step lasts between about 5 seconds to 150 seconds. In another embodiment of the present invention, the heating step preferably lasts between about 20 seconds and 100 seconds.

As previously indicated, the inventive process may also be utilized when forming both planar and vertical selection transistors in DRAM or memory type devices. According to another embodiment of the present invention, there is a method of decreasing the density of dielectric interface traps in an integrated memory device, wherein the method includes steps as described in the following. In a first step a semiconductor substrate is provided for forming an integrated circuit device. The forming of the device is usually conducted by a combination of lithographic, etching, deposition, and other related techniques. Forming the integrated circuit device includes forming a field effect transistor including at least one dielectric layer on the semiconductor substrate followed by heating the semiconductor substrate, including the field effect transistor and dielectric layer, in a pressurized atmosphere comprising at least one gaseous halogen compound.

Turning now to FIG. 5, an integrated circuit device, which may be formed according to an embodiment of the present invention, is shown. The integrated device shown here is a planar transistor with a stacked gate, similar to the planar transistor shown in FIG. 2 of a trench capacitor DRAM memory cell. The planar transistor 500, a type of field effect transistor, is formed on a semiconductor substrate 510 comprising doped regions 570, 580. The doped regions 570 and 580 may be either a source or drain type region. A dielectric layer 560 is formed on the semiconductor substrate 510, as well as the doped regions 570, 580. On top of the dielectric layer 560 three elements 520, 530, and 540 are structured, which may comprise a semiconductor, a metal, an alloy, or a composite material. These elements 520, 530, and 540 may form a so-called gate stack in selection field effect transistor of a DRAM memory cell on an integrated memory device. In this case, the lower element 540 may comprise poly-silicon, the center element 530 a metal-silicon alloy, such as tungsten-silicide (WSi), and the upper element 520 may comprise an insulator, such silicon-nitride (Si₃N₄).

The elements 520, 530, and 540 may be isolated from underlying electronic elements, such as the doped regions 570 and 580, or may also be in electric contact with electronic entities formed below them. The dielectric layer 560 forms interfaces 550 and 590 toward a semiconductor element, such as the semiconductor substrate 510, or toward the element 540, which may comprise a semiconductor, a metal, an alloy, or a composite material. Although many of the aforementioned high-k dielectric materials are possible to use when forming the dielectric layer 560, preferably hafnium-silicon-oxy-nitride HfSiON or aluminum oxide (Al₂O₃) are chosen as the dielectric material.

Subsequent to formation of the dielectric layers 560 on the planar transistor 500, the semiconductor substrate 510, including doped regions 570, 580 and dielectric layer 560, is heated in an atmosphere comprising at least one gaseous halogen compound, preferably a diluted mixture of nitrogen triflouride (NF₃) in argon (Ar), nitrogen (N₂), or oxygen (O₂). Preferably the concentration of gaseous halogen compound is about 0.5 to 10 parts per million (ppm) gaseous halogen compound in Ar, N₂, or O₂. Concentration of the “passivating” atmosphere may best be controlled by using a pre-diluted stream of gaseous halogen compound for example NF₃ in Ar. Furthermore, the heating step can be readily incorporated within current integrated circuit manufacturing processes and requires lower thermal budgets which will be required for future high-k dielectric solutions. In another embodiment of the invention, the passivating atmosphere mixture including the gaseous halogen compound is pressurized to improve passivation of the dielectric layer. The pressure of the atmosphere within the reaction chamber is preferably about 200 Torrs, although any set point between 10 and 1000 Torr is also acceptable, depending on process specifications.

Because utilization of high-k dielectrics may cause an increased density of dielectric interface traps at interfaces between two different materials, such as at interfaces between a dielectric and a semiconductor or between a dielectric and a semiconductor-metal alloy, a method of reducing DIT will be helpful in increasing high-k dielectric reliability in DRAM memory. Increased density of dielectric interface traps ultimately results in undesired generation/recombination currents, which cause a reduction in the data retention time. A reduced data retention time of an integrated memory device strongly affects and reduces the overall performance of such an electronic memory device.

With the inventive method of processing an integrated circuit device in gaseous halogen compounds after formation of at least one dielectric layer on the semiconductor substrate, one of the drawbacks of high-k dielectric utilization, namely increased density of dielectric interface traps, decreases. It is believed that annealing the dielectric layer within a pressurized atmosphere comprising gaseous halogen containing compounds passivates the interfaces between a dielectric layer and other components, such as the semiconductor substrate, better than heating without a pressurized atmosphere. Thus, with the additional inventive process incorporated into integrated circuit device fabrication, integration can be drawn further, the minimum size of the electronic elements can be reduced, and the number of memory cells on a chip can be increased. In summary, the invention allows for an enhancement of the overall performance of integrated devices and integrated memory devices especially, where integration is directly related to the device performance.

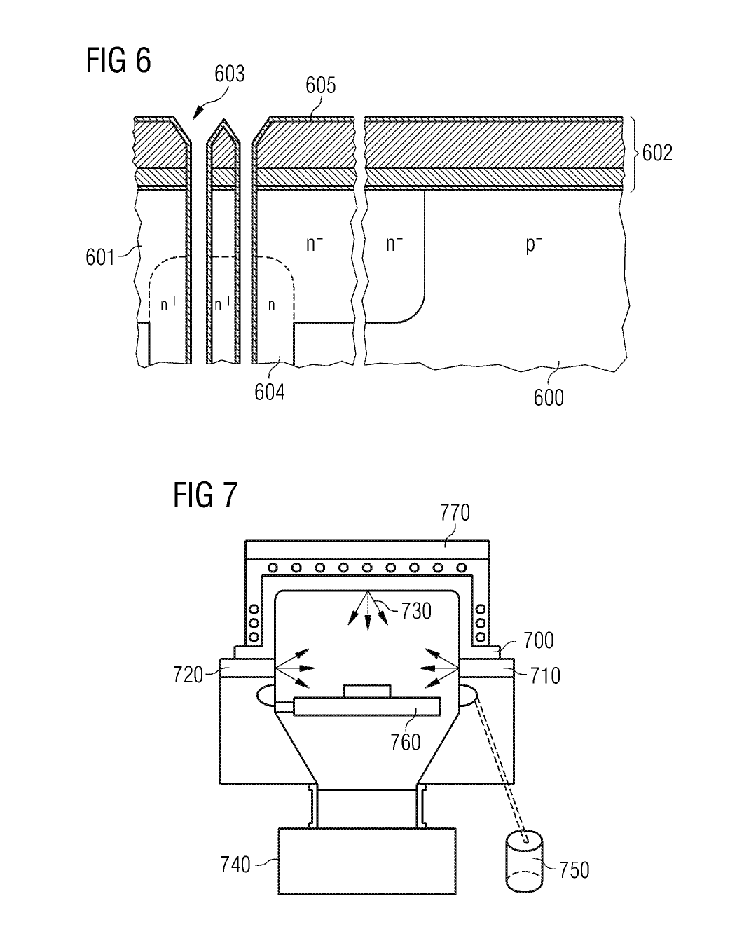

FIG. 6 shows an integrated circuit device which may be formed according to an embodiment of the present invention. This embodiment of the invention is explained on the basis of a process sequence for forming a DRAM memory. In this case, the individual structures of the DRAM memory are preferably formed with the aid of silicon planar technology which comprises a sequence of individual processes. Generally, each process transpires over the whole surface area of a silicon semiconductor wafer whereas a local alteration of the silicon substrate is carried out in a targeted manner by means of suitable masking layers. During the DRAM memory fabrication, a multiplicity of dynamic memory cells is formed simultaneously. However, only some of the process sequences that may incorporate the present inventive process into the DRAM memory fabrication are shown.

FIG. 6 shows a cross section through a semiconductor substrate, in this case a silicon wafer, shown schematically and exemplifies a process sequence according to the invention for fabricating a DRAM memory in silicon planar technology, in particular the trench capacitor. A memory cell region and a peripheral logic region are provided here on the silicon wafer. The memory cells of the DRAM memory are composed of a planar field effect transistor and a trench capacitor. The peripheral logic region contains various components, the switching transistors being fabricated in CMOS technology. Further processing of the semiconductor substrate beyond an application of the present invention, is not shown. Because the DRAM structure is not completed in these figures, the complete fabrication process will not be explained or shown and can be found in the prior art.

The starting material is a p⁻-doped semiconductor substrate 600, in this case silicon, in which an n⁻-doped memory cell region 601 is defined by means of a lithography step and a subsequent ion implantation. A multilayer masking layer 602 for trench etching is then applied on the semiconductor substrate and the storage capacitor region is defined with the aid of a further lithography step. An etching mask is then produced from the masking layer 602 with the aid of an anisotropic etch. An anistropic silicon etch is subsequently carried out in order to form trenches 603 for the storage capacitors which have a depth of 3 to 10 μm.

In a next process sequence, the buried outer capacitor electrode is then formed by producing an n⁺-doped buried plate electrode 604. After fabrication of the buried plate electrode 604, a dielectric intermediate layer 605 is then formed in the trenches 603 and on the n⁻-doped memory cell region 601 and n⁺-doped buried plate electrode 604. Any of the aforementioned high-k dielectric materials may be chosen as the dielectric material.

After formation of the n⁻-doped memory cell region 601, the trench capacitors 603, the n⁺-doped plate capacitor electrode 604, all on the semiconductor substrate 600, and deposition of the dielectric layer 605 on those elements, the silicon wafer is heated in an atmosphere of at least one gaseous halogen compound. The heating step is carried out in an atmosphere comprising at least one gaseous halogen compound, preferably a diluted mixture of nitrogen triflouride (NF₃) in argon (Ar), nitrogen (N₂), or oxygen (O₂). However, other gaseous halogen compounds are also available such as fluorine (F₂), chlorine (Cl₂), and hydrochloric acid (HCl). Preferably the concentration of gaseous halogen compound is about 0.5 to 10 parts per million (ppm) gaseous halogen compound in Ar, N₂, or O₂. The halogen compound concentration of the atmosphere may best be controlled by using a pre-diluted stream of gaseous halogen compound for example 0.1% nitrogen triflouride (NF₃) in argon (Ar). Furthermore, the heating step can be readily incorporated within current integrated circuit manufacturing processes and requires lower thermal budgets which will be required for future high-k dielectric solutions. In another embodiment of the invention, the atmosphere mixture including the gaseous halogen compound is pressurized to improve passivation of the dielectric layer. The pressure of the atmosphere within the reaction chamber is preferably about 200 Torr though the range may be between about 10 and 1000 Torr.

The heating step should last between about 20 to 100 seconds though it may last anywhere between about 5 to 150 seconds. The reaction chamber should heat the semiconductor substrate and dielectric layer preferably at a temperature between about 700° C. to 850° C., although the temperature range may also be between about 500° C. to 1500° C.

Turning now to FIG. 7, a standard rapid thermal processing (RTP) unit, commonly used during integrated circuit device fabrication, is shown. Preferably, RTP equipment would be used to facilitate the heating step of the present invention, although other batch furnace processing tools may also be used to implement the heating step of the present invention. RTP units and other heating tools are commonly used during integrated circuit device fabrication with the RTP unit shown here serving only as an example such heating tools. Other types of RTP and furnace units not shown may also be used to implement the current invention.

In FIG. 7, the RTP unit has a closed reaction chamber 700 in which three gas inlets 710, 720, 730 are provided, by which the desired gaseous halogen compound may be introduced and the atmospheric halogen composition controlled during the heating step. Preferably, argon (Ar) and nitrogen trifluoride (NF₃) are fed into the reaction chamber via the gas inlets. Alternatively, other embodiments of the present invention may instead employ gaseous halogen compounds such as fluorine (F₂), chlorine (Cl₂), hydrochloric acid (HCl), and halogenated hydrocarbons, any of which may be diluted with argon (Ar), nitrogen (N₂), or oxygen (O₂). Said halogenated hydrocarbons are preferably chlorinated hydrocarbons and fluorinated hydrocarbons. Said chlorinated hydrocarbons are preferably Trans-1,2-Dichloroethylene (TLC) (C₂H₂Cl₂), Trichloroethylene (TCE) (C₂HCl₃) and Trichloroethane (C₂H₃Cl₃). A pressure pump configuration 740 for pressurizing the reaction chamber and also a cleaning device 750 are provided on the reaction chamber 700. In a preferred embodiment, the gaseous halogen compound will be pre-diluted for improved concentration control, for example 0.1% nitrogen trifluoride (NF₃) in argon (Ar). The heating step processing time lasts preferably between about 20 to 100 seconds, though processing time may be as short as 5 seconds or as long as 150 seconds, depending on individual process specifications and needs. The pressure of the atmosphere within the reaction chamber is preferably about 200 Torr though the range may be between about 10 and 1000 Torr.

The processed semiconductor substrate forming an integrated circuit including the dielectric layer over the semiconductor substrate is disposed on a carrier plate 760, preferably a heatable carrier plate, in the reaction chamber 700. In order to anneal the dielectric layer in a pressurized atmosphere comprising at least one gaseous halogen compound, a heating device 770 is provided in order to heat the reaction chamber to a desired set temperature.

Results from implementation of this inventive process indicate significantly reduced diffusion of dopants and therefore longer effective devices. Additionally, reduced overlap capacitances, perhaps indicating a reduced out-diffusion along the dielectric interface, also have been observed. In some instances, incorporation of the present invention to current integrated circuit device fabrication processes, such as DRAM fabrication, augments the range of available high-k dielectrics that may replace conventional SiO₂ dielectric layers, some of which may not be possible to implement in current fabrication processes without the presently disclosed inventive process. Furthermore, “halogenating,” as the inventive process may be termed, the interface between dielectric and semiconductor or other dielectric interfaces may be incorporated without major modification to current RTP or batch furnace tools keeping tool complexity and price reasonable. For plasma nitrided gate oxides, which form the gate dielectric, high thermal budget post nitridation anneals are required in order to achieve reasonable low DIT levels. Performing these anneals in diluted gaseous halogen compounds such as NF₃ may lead to improved DIT at significantly lower thermal budgets. Shorter overall process times of integrated circuit device manufacture may also result.

The preceding description only describes advantageous exemplary embodiments of the invention. The features disclosed therein and the claims and the drawings can, therefore, be essential for the realization of the invention in its various embodiments, both individually and in any combination. While the foregoing is directed to embodiments of the present invention, other and further embodiments of this invention may be devised without departing from the basic scope of the invention, the scope of the present invention being determined by the claims that follow.

What is claimed is:

1. A method of decreasing the density of dielectric interface traps in an integrated circuit device, comprising:
providing a semiconductor substrate;
processing the semiconductor substrate to form an integrated circuit device including forming at least one dielectric layer on the substrate; and
heating the semiconductor substrate including the dielectric layer in an atmosphere comprising at least one gaseous halogen compound.

2. The method of claim 1 wherein pressure is applied during the heating step.

3. The method of claim 2 wherein the pressure is between about 10 and 1000 Torr.

4. The method of claim 2 wherein the pressure is about 200 Torr.

5. The method of claim 1 wherein the gaseous halogen compound comprises at least one of the gases: fluorine (F₂), chlorine (Cl₂), hydrochloric acid (HCl), nitrogen trifluoride (NF₃) and halogenated hydrocarbons.

6. The method of claim 1 wherein the atmosphere comprises argon.

7. The method of claim 1 wherein the atmosphere comprises N₂ and O₂.

8. The method of claim 1 wherein the dielectric layer comprises a high-k dielectric.

9. The method of claim 1 wherein the dielectric layer is chosen from the group consisting of SiO₂, S₃N₄, SiON, Ta₂O₅, Al₂O₃, HfO₂, ZrO₂, La₂O₃, Y₂O₃, Hf—Al—O, AlₓZr₁₋ₓO₂ La—Al—O, HfSiO₄, ZrSiO₄, La—Si—O, Y—Si—O, Gd₂O₃, Yb₂O₃, Dy₂O₃, Nb₂O₅, BaₓSr₁₋ₓTiO₃, SrTiO₃, TiO₂, and HfSiON.

10. The method of claim 1 wherein the temperature of the heating step is between about 500° C. to 1500° C.

11. The method of claim 1 wherein the temperature of the heating step is between about 700° C. to 850° C.

12. The method of claim 1 wherein the atmosphere comprises between about 0.5 to 10 parts per million gaseous halogen compound.

13. The method of claim 1 wherein the heating step lasts between about 5 seconds to 150 seconds.

14. The method of claim 1 wherein the heating step lasts between 20 seconds and 100 seconds.

15. The method of claim 1 wherein the heating step is preformed for a duration and at a pressure predetermined to decrease the density of dielectric interface traps at the interface of the substrate and the dielectric layer of the integrated memory device.

16. A method of decreasing the density of dielectric interface traps in an integrated memory device, comprising:
providing a semiconductor substrate;
processing the semiconductor substrate to form at least one field effect transistor including forming at least one dielectric layer on the substrate; and
heating the semiconductor substrate including the dielectric layer in a pressurized atmosphere comprising at least one gaseous halogen compound.

17. The method of claim 16 wherein the atmosphere comprises between about 0.5 to 10 parts per million gaseous halogen compound.

18. The method of claim 16 wherein the heating step lasts between about 5 seconds to 150 seconds.

19. The method of claim 16 wherein the heating step lasts between about 20 seconds to 100 seconds.

20. The method of claim 16 wherein the temperature of the heating step is between about 500° C. to 1500° C.

21. The method of claim 16 wherein the temperature of the heating step is between about 700° C. to 850° C.

22. The method of claim 16 wherein the dielectric is chosen from the group consisting of SiO₂, S₃N₄, SiON, Ta₂O₅, Al₂O₃, HfO₂, ZrO₂, La₂O₃, Y₂O₃, Hf—Al—O, AlₓZr₁₋ₓO₂ La—Al—O, HfSiO₄, ZrSiO₄, La—Si—O, Y—Si—O, Gd₂O₃, Yb₂O₃, Dy₂O₃, Nb₂O₅, BaₓSr₁₋ₓTiO₃, SrTiO₃, TiO₂, and HfSiON.

23. The method of claim 16 wherein the gaseous halogen compound comprises at least one of the gases: fluorine (F₂), chlorine (Cl₂), hydrochloric acid (HCl), nitrogen trifluoride (NF₃) and halogenated hydrocarbons.

24. The method of claim 16 wherein the atmosphere comprises argon.

25. The method of claim 16 wherein the atmosphere comprises N₂ and O₂.

26. The method of claim 16 wherein the pressure is between about 10 and 1000 Torr.

27. The method of claim 16 wherein the pressure is about 200 Torr.

28. The method of claim 16 wherein the heating step is preformed for a duration and at a pressure predetermined to decrease the density of dielectric interface traps at the interface of the substrate and the dielectric layer of the integrated memory device.
